(19) United States
(12) Patent Application Publication
(10) Pub. No.: US 2004/0150944 A1
(43) Pub. Date: Aug. 5, 2004

(54) Docking station adapted to accept multiple different electronic devices

(76) Inventors: Daniel J. Byrne, Fort Collins, CO (US); Alan P. Lemke, Fort Collins, CO (US); Theodore B. Ziemkowski, Loveland, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/356,845

(22) Filed: Feb. 3, 2003

(51) Int. Cl. H05K 5/00

(52) U.S. Cl. 361/683

(57) ABSTRACT

The present invention accommodates a device from a plurality of different portable electronic devices to be docked to a docking station. A docking station adapts a power supply output to a power supply input compatible with the docked device. The docking station includes a recognition interface that identifies the docked device and a power converter that adapts the power supply output to the power supply input of the identified device. A docking station adaptor includes a power converter and receives the device to be docked to the docking station. The adaptor adapts the power supply output from the docking station to the received device power supply input. A docking system interfaces the device to a common docking station. The system includes the device and the docking station. A method adapts the device to be docked to a common docking station.

### TECHNICAL FIELD

The invention relates to portable electronic devices. In particular, the invention relates to docking stations used with portable electronic devices, such as digital cameras.

### BACKGROUND OF THE INVENTION

Portable, battery-powered devices, such as digital cameras for example, may employ a ‘docking station’ as a means of interconnecting with other equipment or systems. Docking stations are used with a wide variety of portable, battery-powered devices including, but not limited to, a digital camera, a personal digital assistant (PDA), a laptop computer, a cellular telephone and a MP3 player.

Unfortunately, docking stations tend to be relatively device-specific. In other words, a docking station for a particular device type, such as a digital camera, will not generally accommodate another device, such as a laptop computer or a PDA. Moreover, even within device types, a separate docking station is generally required for each different device model. In particular, a given model of a device often has unique mechanical, electrical and power supply interface characteristics when compared to other device models, even within the same general device type (e.g., digital cameras). Thus, docking stations are often designed and manufactured to conform to a particular device type and device model. As a result, a user with multiple devices often ends up with multiple docking stations that, at the very least, may unnecessarily clutter a work area and at worst, may actually negatively interfere with one another.

Accordingly, it would be advantageous to have a means for adapting a docking station for use with more than one particular device type and/or device model. In particular, a means for adapting a power supply of the docking station to accommodate multiple portable electronic devices is desirable. Such a docking station with a device-adaptive power supply would solve a long-standing need in the area of docking stations for portable electronic devices.

### SUMMARY OF THE INVENTION

The present invention adapts a docking station to accommodate more than one device type to be interfaced or ‘docked’ thereto. In particular, the present invention adapts a power supply output of the docking station to conform to a power supply input compatible with any device from a plurality of different portable electronic devices. The devices of the plurality may be of the same type but of different models such as, but not limited to, different models of digital cameras, for example. Additionally, the devices of the plurality may be of different types such as, but not limited to, a laptop computer, a digital camera, a personal digital assistant (PDA), a cellular telephone, a consumer electronic toy, and an MP3 player. As such, the present invention applies to virtually any docking station used with a portable electronic device and, by extension, to virtually any portable electronic device that may be interfaced to such a docking station.

In one aspect of the present invention, a docking station is provided. The docking station comprises means for recognizing a device docked to the docking station, the device being any device of a plurality of different devices, and means for converting a power supply output of the docking station. The means for converting adapts the power supply output to a power supply input of the recognized device.

In another aspect of the invention, a power-converting adaptor for use with a docking station is provided. The power-converting adaptor comprises a power converter that converts or adapts a power supply output of the docking station to a power supply input compatible with a device being docked. As such, the adaptor may be employed with conventional docking stations and renders the docking station supportive of any device from a plurality of different portable electronic devices for docking.

In another aspect of the present invention, a docking system that interfaces any device from a plurality of different portable electronic devices to a docking station is provided. In yet another aspect of the present invention, a method of adapting a device to be docked to a common docking station is provided.

One or more of the following features and/or advantages may be realized by the present invention. The docking station recognizes and adapts to power supply inputs compatible with more than one device type and/or device model by virtue of the means for recognizing according to the present invention. As such, a single adapted docking station according to the present invention may replace multiple conventional docking stations in servicing multiple different devices. The docking station adaptor may be used with existing docking stations and devices without requiring a redesign of the docking stations or devices. The docking station adaptor according to the present invention may be employed to use a single, conventional docking station with any device from multiple, essentially conventional, portable electronic devices. Certain embodiments of the present invention have other advantages in addition to and in lieu of the advantages described hereinabove. These and other features and advantages of the invention are detailed below with reference to the following drawings.

### BRIEF DESCRIPTION OF THE DRAWINGS

The various features and advantages of the present invention may be more readily understood with reference to the following detailed description taken in conjunction with the accompanying drawings, where like reference numerals designate like structural elements, and in which:

FIG. 1 illustrates a block diagram of a docking station according an embodiment of the present invention.

FIG. 2 illustrates a block diagram of a docking station according another embodiment of the present invention.

FIG. 3 illustrates a perspective view of an embodiment of the docking station illustrated in FIG. 2.

FIG. 4 illustrates a block diagram of a docking station adaptor according to an embodiment of the present invention.

FIG. 5A illustrates a block diagram of a docking system according to an embodiment of the present invention.

FIG. 5B illustrates a block diagram of a docking system according to other embodiments of the present invention where the docking station adaptor is not included or necessary.

FIG. 6 illustrates a flow chart of an embodiment of a method of adapting multiple devices to a docking station according to the present invention.

### MODES FOR CARRYING OUT THE INVENTION

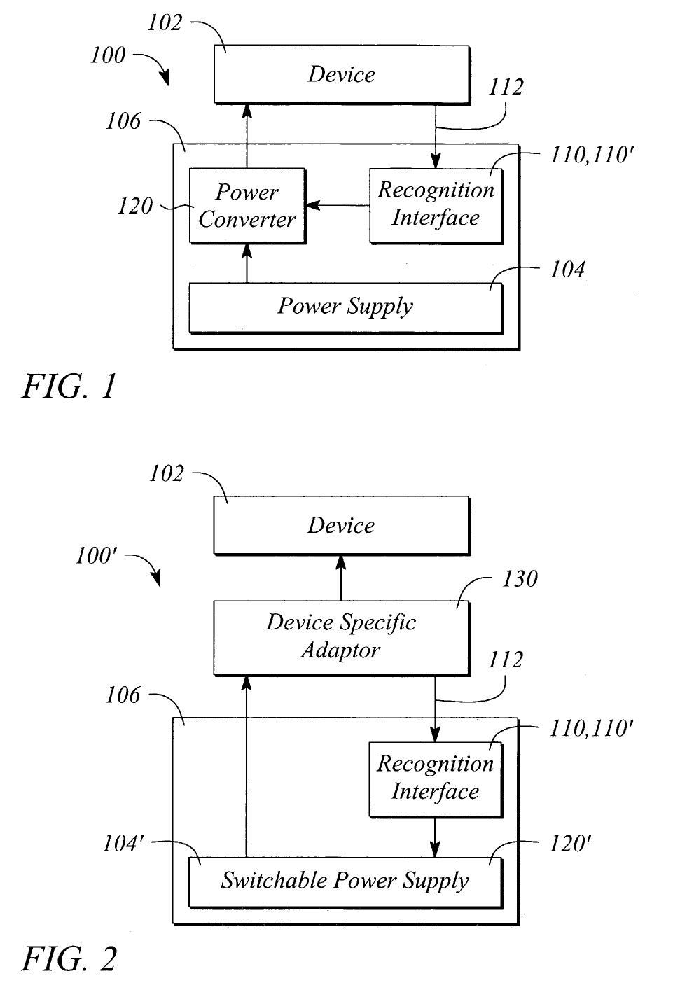

FIG. 1 illustrates a block diagram of a docking station 100 according an embodiment of the present invention. The docking station 100 adapts an output of a docking station power supply to accommodate a device 102 being docked thereto. The docking station 100 comprises a docking station power supply 104, means for recognizing 110 the device 102, and means for adapting or converting 120 an output of the docking station power supply 104. In some embodiments, the docking station power supply 104 is housed in a docking base unit 106. The docking base unit 106 may further provide a mechanical interface that accommodates the device 102. The means for recognizing 110 recognizes the device 102 and communicates a device identification to the means for converting 120. The means for converting 120 adapts the output of the docking station power supply 104 to conform to a power supply input characteristic or requirement of the device 102.

As used herein, ‘docking station’ refers to an apparatus that both holds or mechanically supports the portable device and provides an electrical interface for the device docked thereto. In particular, a docked portable device may use the docking station as an interface for transferring data to and/or from an external system such as, but not limited to, a personal computer (PC) and a color printer. Additionally, the docking station typically supplies power to the docked device. The supplied power may be used to recharge a rechargeable battery of the docked device, for example. The supplied power may also provide operational power to the device while the device is docked to the docking station. Thus for example, a user of a portable, battery-powered digital camera may download photographs from the camera memory while simultaneously recharging the battery of the camera by simply placing (i.e., docking) the digital camera in the docking station.

FIG. 2 illustrates a block diagram of a docking station 100′ that adapts an output of a docking station power supply to a device 102 being docked thereto according another embodiment of the present invention. The docking station 100′ comprises the means for recognizing 110 of the docking station 100. Further, the docking station 100′ comprises either the means for converting 120 and the power supply 104 of the docking station 100 or a switchable power supply 120′, 104′ according to an alternative embodiment that is illustrated in FIG. 2 and further described below. The docking station 100′ further comprises a docking station adaptor 130. The docking station adaptor 130 is preferably a ‘device-specific’ adaptor 130. By ‘device-specific’ it is meant that a unique adaptor 130 is employed for each different device type and/or device model of the device 102. In general, the ‘uniqueness’ of the device-specific adaptor 130 is defined by a relative physical and/or electrical interface difference between the various different device types and/or device models that are interfaced to the docking station 100′. The docking base unit 106 houses the means for recognizing 110 and the means for converting 120 (or the alternative switchable power supply embodiment 120′, 104′) as well as provides or houses a mechanical interface for the docking station adaptor 130.

In some embodiments, the means for recognizing 110 comprises a recognition interface 110. The recognition interface 110 receives a recognition input 112 regarding a device type and/or device model of the device 102. The recognition input 112 may be provided to the recognition interface 110 either automatically or manually. As such, in some embodiments the device 102 itself provides the recognition input 112 automatically when the device 102 is docked with the docking station 100. In other embodiments, the docking station adaptor 130, being specific to a particular device type/model, automatically provides the recognition input 112 to the docking station 100′. The automatically provided recognition input 112 enables the recognition interface 110 to recognize and identify the device 102 as to device type and/or device model. The automatically provided recognition input 112 may be in the form of a mechanical input, an electrical input, an optical input, or a combination thereof.

The recognition input 112 in the form of a mechanical input may be a mechanical coupling structure or ‘key’ built into the device 102 or the adaptor 130. The recognition interface 110 comprises a key receiver that is complimentary to the key. The key cooperatively engages the key receiver when the device 102 or device-specific adaptor 130 is docked with the docking station 100, 100′. A different key configuration may be used with each different device type/model allowing recognition of the device 102 by virtue of which key is received by the key receiver.

For example, a device 102 of a first type may have a pin protruding from a surface of the device 102 that is adjacent to the docking station 100 when the device 102 is docked. The pin may be absent from a device 102 of a second type. When the device 102 of the first type is docked with the docking station 100, the pin depresses a switch of the key receiver thereby automatically providing the recognition input 112 to the recognition interface 110. Similarly, the absence of the pin on the device 102 of the second type means that the switch is not depressed when the device 102 of the second type is docked. Thus, whether or not the switch is depressed when the device 102 is docked serves as a recognition input 112 that enables the recognition interface 110 to distinguish between devices 112 of the first type and the second type.

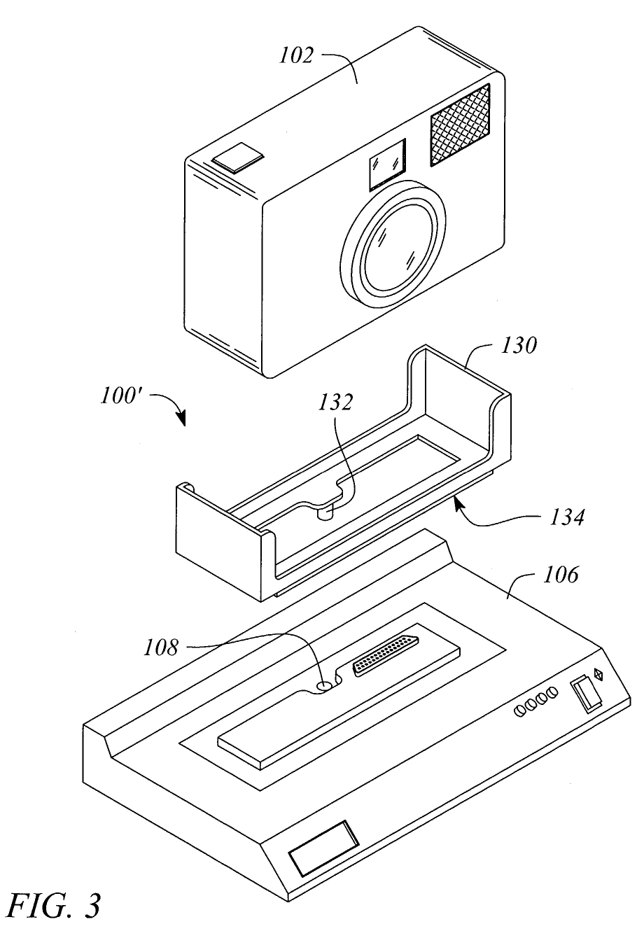

FIG. 3 illustrates a perspective view of an embodiment of the docking station 100′ illustrated in FIG. 2. In the exemplary embodiment of the docking station 100′ illustrated in FIG. 3, a pin 132 may or may not be present or protruding from a contacting surface 134 of the adaptor 130. For example, a device 102 of a first type may employ a device-specific adaptor 130 without the pin while a device 102 of a second type employs a device-specific adaptor 130 having the protruding pin 132. Alternatively, a device-specific adaptor 130 may have a retractable pin 132 that is retracted for a device 102 of a first model or first type, and protrudes for a device of a second model or second type. When present or protruding, the pin 132 contacts and activates a switch (not illustrated) of the recognition interface 110 by way of a receptacle 108 within the base unit 106 of the docking station 100′ as the adaptor 130 is connected to the docking station 100′. The activated switch of the recognition interface 110 determines an output conversion of the power supply 104, 104′ of the docking station 100′ thereby automatically adapting the docking station 100′ to the device 102.

In other exemplary embodiments, different locations of one or more pins on devices 102 of different types or models and/or on device-specific adaptors 130 are employed to enable the recognition interface 110 to recognize and identify devices 102 of different types or models. In yet other exemplary embodiments, one or more depressions or apertures may be provided on the device 102 and/or on the adaptor 130. One or more probes mounted to switches in the recognition interface 110 engage the depressions when the device 102 or the device-specific adaptor is docked. A pattern of depressions, as sensed by the switch-mounted probes, is used to determine the type/model of the device 102 from among a number of known device 102 types/models. One skilled in the art may readily devise a wide variety of other mechanical key and key receiver configurations for realizing the automatic recognition of a device 102 type or model using a mechanical means. All such mechanical key and key receiver configurations are within the scope of the present invention.

Alternatively, the automatic recognition input 112 may be in the form of an electrical input to the recognition interface 110 of the docking station 100, 100′. In particular, the device 102 and/or device-specific adaptor 130 may provide an electrical interface (not illustrated) that is probed by the recognition interface 110 of the docking station 100, 100′ upon the device 102 being docked, thereby providing the automatic recognition input 112. Alternatively, the device 102 and/or device-specific adaptor 130 may provide an electrical signal (not illustrated) to the recognition interface 110 as the automatic recognition input 112. The recognition interface 110 essentially uses the electrical interface or the electrical signal to recognize the particular device type/model.

For example, the electrical interface may comprise a connector, specific pins of which are one or more of connected to a ground potential, connected to a non-zero voltage potential (e.g., V+ or V−), or are ‘open-circuited’. By ‘open-circuited’ it is meant that a pin of the connector is not at any specific voltage potential and represents an essentially open-circuit impedance to an external circuit connected thereto. A pattern of such connections serves to identify the type and/or model of the device 102. The recognition interface 110 comprises a mating connector (not illustrated) for interconnecting to the electrical interface of the device 102 and circuitry (not illustrated) for probing the electrical interface. In essence, the recognition interface 110, through the mating connector, probes the connector on the device 102 when the device 102 is docked in the docking station 100. Through the probing, the recognition interface 110 determines the specific connection pattern (e.g., which of the connector pins are connected to ground, V+, V−, and open-circuit) of the device 102 connector. Using the determined pattern, the recognition interface 110 identifies the device 102 type and/or model. The circuitry may be hardwired circuitry, discrete logic circuitry, or a controller such as a microprocessor that executes a computer program to accomplish the probing. Similarly, the electrical interface may be located on the adaptor 130 instead of or in addition to the device 102 for use in the docking station 100′. One skilled in the art is familiar with and may readily design circuitry for probing the electrical interface without undue experimentation.

In another example embodiment of the docking station 100, 100′, the device 102 and/or device-specific adaptor 130 provides an electrical signal to the recognition interface 110 upon docking. Examples of such electrical signals include, but are not limited to, a serial digital data stream, an analog voltage level, and a modulated analog signal. The signal, after being recognized by the recognition interface 110, serves to identify the docked device 102 type and/or model. In yet another example, the device 102 and/or the device-specific adaptor 130 produce an optical signal. The recognition interface 110 receives and employs the optical signal as the automatic recognition input 112. Alternatively, the recognition interface 110 may optically scan a bar code on the device 102 or the device-specific adaptor 130 to obtain the recognition input 112. Other such electrical, optical, and combinations of electrical, optical and mechanical inputs for identifying the device 102 are familiar to and may be readily devised by one skilled in the art. All such electrical, optical and combined electrical, optical, and mechanical inputs serving as the automatic recognition input 112 are within the scope of the present invention.

In other embodiments of the docking station 100, 100′, a user of the device 102 manually provides the recognition input 112. In particular, the manual recognition input 112 may be any means by which the user manually identifies the device 102 type and/or model to the recognition interface 110 of the docking station 100, 100′. For example, a multi-position switch (not illustrated) on the docking station 100, 100′ base unit 106 may be employed as the manual recognition input 112. A first position on the switch may identify a device 102 of a first type and/or model. A second position on the switch may identify a device 102 of a second type/model and so on. The user, by selecting an appropriate switch position, provides the manual recognition input 112 to the recognition interface 110. One skilled the art may readily devise additional manual recognition inputs 112, that may or may not use a switch, all of which are within the scope of the present invention.

While described in terms of a simple switch or set of switches that change the power supply output based on the identified device 102 type/model, the recognition interface 110 may further comprise a controller and a computer program executed by the controller. The controller may be a microcomputer or microprocessor and an associated computer memory. The computer program may be stored in the computer memory as firmware or software, for example. The instructions of the computer program, when executed by the controller, receive the recognition input 112, determine a device identification from the received recognition input 112, and provide an appropriate control input to the means for converting 120, 120′ as a device identification. Likewise, the recognition interface 110 may be implemented using hardwired logic in the form of a programmable gate array or an application specific integrated circuit (ASIC).

In some embodiments of the docking station 100, 100′, the means for converting 120 is a power converter 120. The power converter 120 converts an output voltage and/or current of the docking station 100, 100′ power supply 104 into another voltage and/or current. The action of the power converter 120 is controlled by the device identification received by the power converter 120 from the recognition interface 110. As such, the voltage and/or current produced by the power converter 120 depend on the docked device 102 type/model.

For example, the power converter 120 may be a switchable or variable voltage DC-DC converter 120 such as, but not limited to, a MAX679 Step Up Regulated Charge Pump Converter. The MAX679 Step Up Regulated Charge Pump Converter is marketed by Maxim Integrated Products, Sunnyvale, Calif., USA. As with many such power converters 120, the exemplary MAX679 Step Up Regulated Charge Pump Converter has a control input that configures or controls an output voltage of the converter 120. Using the control input, the DC-DC converter 120 may be configured to produce an output voltage of either +3V or +6V, for example. Thus, if the recognition interface 110 identifies a device 102 type that requires +3V, the control input is used to configure the power converter 120 such that an output voltage of the power supply 104 is converted into +3V. Alternatively, when a device 102 requiring +6V is identified, the control input is employed to configure the power converter 120 to produce +6V from the output voltage of the power supply 104. Other voltages, as well as more than two selectable outputs, may be provided by the exemplary DC-DC power converter 120 and still be within the scope of the present invention.

In another example embodiment, the means for converting power 120 may be a linear regulator 120 such as, but not limited to, a REG103-A Low Drop-out Linear Regulator with an adjustable output voltage. The exemplary REG103-A Low Drop-out Linear Regulator is marketed by Texas Instruments, Inc., Dallas, Tex. The exemplary linear regulator 120 may be configured to accept an input of +7V for example and convert the input to an adjustable output voltage of +3.3V. The input voltage of +7V may be an output voltage of the docking station power supply 104. Likewise, the output voltage of +3.3V may be compatible with a power supply input requirement of the device 102 being adapted. Similarly, if another device 102 that requires a power supply input voltage of +5V is to be docked, the exemplary linear regulator 120 may be adjusted to convert +7V to +5V. Thus, the device identification may be used to adjust the output voltage of the exemplary regulator 120 such that the output voltage of the docking station 100 is converted to a voltage that is compatible with the identified device 202.

In other embodiments, the means for converting 120′ is incorporated into the docking station power supply 104′ as a means for controlling or switching 120′ an output voltage of the power supply 104′. For example, the power supply 104′ may have a controllable output voltage and/or current. Control of the output voltage and/or current is provided by the recognition interface 110 by way of the device identification. In an exemplary embodiment, the power supply 104′ may have an output voltage that is switchable between +3.5 V and +5 V. When a device 102 that requires +3.5V is identified by the recognition interface 110, the exemplary power supply 104′ is switched to provide +3.5V. Alternatively, when a device 102 that requires +5V is identified, the power supply 104′ switches and provides +5V. One skilled in the art is familiar with both controllable power converters 120 and power supplies 104 having means 120′, 104′ of controllable or switchable output voltage and/or current.

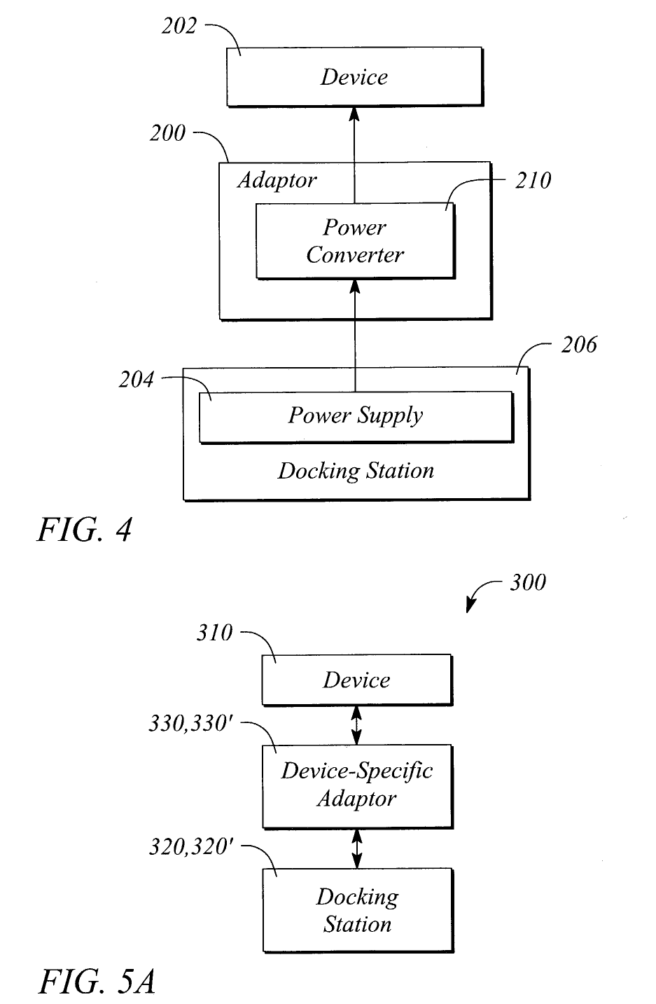

FIG. 4 illustrates a block diagram of a docking station adaptor 200 that provides power conversion according to an embodiment of the present invention. The power-converting, docking station adaptor 200 mechanically and electrically adapts a device 202 to a docking station 206. In particular, the docking station adaptor 200 converts an output of a power supply 204 of the docking station 202 into a form that is compatible with the device 202. In addition, the docking station adaptor 200 adapts a mechanical form factor of the device 202 to be compatible with the docking station 206. The power-converting, docking station adaptor 200 preferably is device-specific. Thus, by employing the adaptor 200 according to the present invention, multiple device type/models may be used with a single docking station 206 without regard for mechanical and power supply compatibility between particular devices 202 and a given docking station 206.

The power-converting, docking station adaptor 200 comprises means for receiving the electronic device 202, means for interfacing to the docking station 206 to dock the received device 202, and means for converting power 210, supported by an adaptor shell (not illustrated). The means for converting power 210 converts an output of a power supply 204 of a docking station 206 from a first voltage and/or current to a second voltage and/or current. As such, the power-converting, docking station adaptor 200 adapts the output of the power supply 204 of the docking station 206 to a power supply input required by the device 202.

For example, the means for converting power 210 may be a DC-DC converter such as, but not limited to, a MAX679 Step Up Regulated Charge Pump Converter. The exemplary DC-DC Converter may be configured to accept an input of +2.5V for example and convert the input to an output voltage of +6V. The input voltage of +2.5V may be an output voltage of the docking station 206 power supply 204. Likewise, the output voltage of +6V may be compatible with a power supply input requirement of the device 202 being adapted. Thus, the device 202 that normally requires a +6V power supply may be docked to the docking station 206 that provides a +2.5V power supply output voltage by using the exemplary power-converting adaptor 200. Similarly, a linear regulator, or any of a wide variety of other devices known in the art for converting power, may be employed as the means for converting power 210 in the power-converting adaptor 200 according to the present invention.

The power-converting, docking station adaptor 200 adapts both a mechanical characteristic and an electrical characteristic of the device 202 to a mechanical characteristic and an electrical characteristic of the docking station 204 using the receiving means and the interfacing means. In particular, the means for receiving the device 202 comprises a mechanical contact in the adaptor 200 shell, such as a receptacle, that is adapted to receive and mechanically hold the device 202. The adaptor receiving means further comprises an electrical contact that electrically connects an input of the received device 202 to an output of the means for converting power 210.

The means for interfacing comprises a mechanical contact and an electrical contact in the adaptor shell. The adaptor interfacing means is complimentary to corresponding contacts in the docking station 206. The adaptor interfacing means provides both mechanical and electrical interconnection to the docking station 206. In particular, the adaptor interfacing means provides electrical interconnection between an output of the docking station 206 power supply and an input of the means for converting power 210. Thus, using the receiving means and the interfacing means of the adaptor 200, the means for converting power 210 electrically connects the device 202 to the docking station 206 and adapts the power output of the docking station 206 to the input power requirement or characteristic of the docked device 202.

Various different device types and/or device models are accommodated by different specific adaptor receiving means while a common adaptor interfacing means may be employed. However it is within the scope of the present invention for the adaptor receiving means to be common or universal among the various device types and models by having a plurality of mechanical contacts and electrical contacts that activate and deactivate depending on the device 202 that is received. Thus whether device-specific or universal, the adaptor 200 adapts the mechanical and electrical characteristics of a device of multiple different devices 202 to a single docking station 206.

The power-converting, docking station adaptor 200 may further comprise an electrical interface converter (not illustrated). The electrical interface converter converts an interface of the device 202 into an interface that is compatible with the docking station 206. For example, the electrical interface converter may comprise a first universal serial bus (USB) connector that connects to the device 202, a second USB connector that connects to the docking station 206 and a cable that connects the first and second USB connectors. The electrical interface converter in this example acts as a ‘pass-through’ interface merely ‘converting’ a connector type of the device 202 to a connector type of the docking station 206. In another example, the electrical interface may comprise connectors that interface to the device 202 and the docking station 206, respectively, and an interface circuit that interconnects the connectors and conditions or transforms one or more signals that pass between the connectors. One skilled in the art is familiar with docking station adaptors that provide a mechanical and electrical interface adaptation.

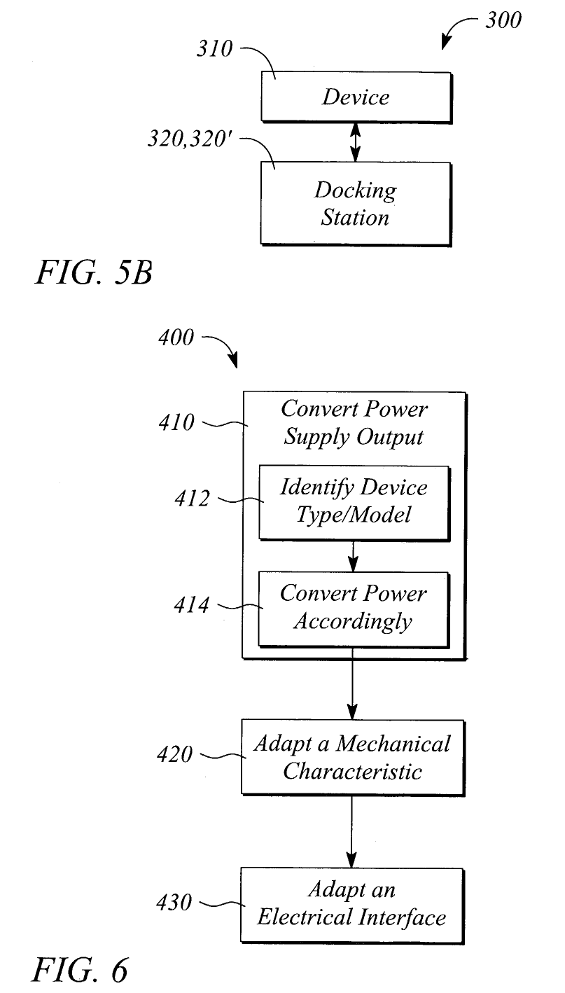

In another aspect of the present invention, a docking system 300 for interfacing more than one device type and/or device model of a portable electronic device 310 to a single docking station 320 is provided. FIG. 5A illustrates a block diagram of a docking system 300 according to some embodiments of the present invention. The docking system 300 comprises a portable electronic device 310. The device 310 may be any device type including, but not limited to, a digital camera, a laptop computer, an MP3 player, and a personal digital assistant (PDA), a cellular telephone, and a consumer electronics toy, and includes any model thereof. The docking system 300 further comprises the docking station 320. Depending on the embodiment, the docking system 300 may further comprise a docking station adaptor 330. FIG. 5A illustrates embodiments of the docking system 300 where the docking station adaptor 330 is included. FIG. 5B illustrates a block diagram of a docking system 300 according to other embodiments of the present invention where the docking station adaptor 330 is not included or necessary.

In some embodiments, the docking station 320 recognizes the device 310 and identifies a device type/model for the device 310. The docking station 320 comprises means for power converting and means for recognizing, such that the station 320 configures a power supply voltage and/or current based on the device identification. As such, the docking station adaptor 330 is not necessary. The docking station 320 of the docking system 300 is preferably the docking station 100, 100′ described herein above. In such an embodiment as docking station 100′ that includes an adaptor, the docking station adaptor 330 may be the docking station adaptor 130 described hereinabove with respect to the docking station 100′. As such, the docking station adaptor 330 provides ‘device/station-compatible’ mechanical and electrical interfaces between the device 310 and the docking station 320, such as that described above for the adaptor 130 and docking station 100′.

In other embodiments, the docking station 320′ does not recognize the device 310. Instead, the docking station adaptor 330′ adapts the device 310 to the docking station 320′. In these embodiments, the docking station 320′ comprises a power supply but need not comprise means for power converting. Instead, the adaptor 330′ comprises the power converting means. In particular, the docking station adaptor 330′ converts a power supply voltage and/or current of the docking station 320′ into a form that is compatible with the device 310. In addition, the docking station adaptor 330′ may adapt a mechanical and electrical interface configuration of the device into a mechanical and electrical interface configuration compatible with the docking station 320′. The docking station adaptor 330′ is preferably the power-converting docking station adaptor 200 described hereinabove. In such embodiments, the docking station 320′ may be the docking station 206 described above, or a conventional docking station, and the device 310 may be any device that may be indirectly interfaced to a docking station 320′ using the device specific adaptor 330′.

In yet another aspect of the present invention, a method 400 of adapting a device of a plurality of portable electronic devices to a common docking station is provided. FIG. 6 illustrates a flow chart of an embodiment of the method 400 of adapting a device from the plurality of devices to a docking station, according to the present invention. The method 400 comprises converting 410 a power supply output of the docking station to a power input that is compatible with the device being docked. The method 400 may further comprise adapting 420 a mechanical characteristic of the device to be compatible with a mechanical characteristic of the docking station. The method 400 may further comprise adapting 430 an electrical interface of the device to be compatible with an electrical interface of the docking station.

In some embodiments, converting 410 comprises identifying 412 the device to the docking station and converting 414 the power accordingly or adaptively, such as by adapting 414 the power supply output to a power supply input compatible with the identified device. For example, a device may be identified 412 that requires a power supply voltage of +3V. Once identified, the docking station may convert 414 a power supply output voltage of +6V into a power supply voltage of +3V that is compatible to the identified device. Alternatively, the device may be identified 412 by a choice of a particular adaptor used. In either embodiment, the docking station may still convert 414 the power supply output voltage into a compatible voltage for the identified device. Alternatively, the adaptor may instead convert 414 the docking station power supply voltage of +6V into the device-specific voltage of +3V, for example, depending on the embodiment. Moreover, the docking station and the adaptor may work in combination to one or both of identify 412 and convert 414, according to the method 400 of the present invention.

Thus, there have been described a docking station that adapts a power supply voltage to accommodate any device from a plurality of different portable electronic devices. Additionally, a power-converting docking station adaptor, a docking system and method for adapting a device from the plurality of different devices to a common docking station have been disclosed. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A docking station comprising:
means for recognizing a device docked to the docking station, the device being any device of a plurality of different devices; and
means for converting a power supply output of the docking station,
wherein the means for converting converts the power supply output to a power supply input compatible with the recognized device.

2. The docking station of claim 1, wherein the means for recognizing communicates a device identification to the means for converting, and wherein the means for converting adapts the power supply output based on the device identification, the means for recognizing comprising:
a recognition interface that receives a recognition input from one or both of the device being docked to the docking station and an adaptor specific to the device being docked, the adaptor further providing a mechanical interface between the device and the docking station.

3. The docking station of claim 1, wherein the means for converting comprises an adjustable power converter between the docking station power supply output and the power supply input of the device, the means for recognizing communicating a device identification to the power converter, the device identification determining an adjustment of the power converter, and
wherein the power converter is housed in one of a base unit of the docking station or an adaptor that is specific to the device being docked, the adaptor accepting the device and mechanically interfacing the device to the docking station base unit.

4. A docking station comprising:
a recognition interface that recognizes a device being docked to the docking station, the device being any device of a plurality of different devices; and
a power converter that converts a power supply output of the docking station to a power supply input compatible with the recognized device.

5. The docking station of claim 4, wherein the recognition interface receives a recognition input and generates a device identification from the recognition input.

6. The docking station of claim 5, wherein the recognition input is received from the device in the form of one or more of a mechanical input, an electrical input, and an optical input.

7. The docking station of claim 5, further comprising an adaptor, wherein the recognition input is received from the adaptor in the form of one or more of a mechanical input, an electrical input, and an optical input and wherein the adaptor is device-specific.

8. The docking station of claim 4, wherein the power converter is an adjustable power converter between the docking station power supply output and the power supply input of the device, the recognition interface communicating a device identification to the power converter, the device identification determining an adjustment of the power converter.

9. The docking station of claim 4, wherein the power converter is located in one of a base unit of the docking station or an adaptor of the device, the adaptor further providing a mechanical interface between the device and the docking station base unit.

10. The docking station of claim 4, wherein the power converter is incorporated into a switchable power supply of the docking station.

11. A power-converting adaptor for use with a device being docked to a docking station comprising:
a power converter within an adaptor shell that converts a power supply output of the docking station to a power supply input compatible with the device being docked.

12. The power-converting adaptor of claim 11 further comprising:
a mechanical interface in the adaptor shell that is adapted to receive and mechanically hold the device; and
an electrical contact in the adaptor shell that electrically connects the received device to an output of the power converter, such that the docking station supports any device of a plurality of portable electronic devices for docking.

13. A docking system that interfaces any device from a plurality of different portable electronic devices to a docking station comprising:
a portable electronic device having a power supply input, the device being of any type and any model of device from the plurality of portable electronic devices;
a docking station having a power supply output;
a recognition interface that recognizes the portable electronic device when docked to the docking station; and
a power converter, the recognition interface communicating a device identification to the power converter, the power converter converting the power supply output from the docking station to a power compatible with the power supply input of the docked device.

14. The docking system of claim 13, wherein one or both of the recognition interface and the power converter are enclosed in the docking station.

15. The docking system of claim 13, further comprising:
an adaptor that receives the device to be docked, the adaptor interfacing to the docking station, the adaptor adapting one or both of a mechanical interface and an electrical interface of the received device to a respective one or both of a mechanical interface and an electrical interface of the docking station.

16. The docking system of claim 15, wherein the adaptor is device-specific, such that each device of the plurality of portable electronic devices has a unique adaptor, each unique adaptor having complimentary means for interfacing to the docking station, one or both of the device and the adaptor providing the device identification to the recognition interface.

17. The docking system of claim 15, wherein the adaptor comprises the power converter, such that the adaptor adapts the power supply output from the docking station to the power supply input of the docked device.

18. The docking system of claim 13, wherein the portable electronic device is selected from any model of a digital camera, a laptop computer, an MP3 player, a cellular telephone, a consumer electronics toy, and a personal digital assistant (PDA).

19. A method of adapting a device to be docked to a common docking station for power comprising:
converting a power supply output of the common docking station to a power supply input compatible with the device being docked to the docking station, the device being from a plurality of different portable electronic devices.

20. The method of claim 19, wherein converting comprises identifying the device from the plurality of portable electronic devices, and adapting the power supply output to the power supply input of the identified device.

21. The method of claim 20, wherein identifying the device comprises using an adaptor that is specific to the device being docked, one or both of the adaptor and the device providing a device identification representing the device being docked.

22. The method of claim 20, wherein identifying the device comprises recognizing the device being docked based on a device identification, and adapting the power supply output to the power supply input of the docked device based on the device identification.

23. The method of claim 20, wherein converting the power supply output comprises using an adaptor that is specific to the device being docked, the adaptor adapting the power supply output to the power supply input of the device.
